(19) United States
(12) Patent Application Publication
(10) Pub. No.: US 2013/0038174 A1
(43) Pub. Date: Feb. 14, 2013

(54) ULTRASONIC SENSOR

(71) Applicants: Boum Seock KIM, Gyeonggi-do (KR); Eun Tae Park, Gyeonggi-do (KR)

(72) Inventors: Boum Seock KIM, Gyeonggi-do (KR); Eun Tae Park, Gyeonggi-do (KR)

(73) Assignee: SAMSUNG ELECTRO-MECHANICS CO., LTD., Suwon (KR)

(21) Appl. No.: 13/567,674

(22) Filed: Aug. 6, 2012

(30) Foreign Application Priority Data
Aug. 8, 2011 (KR) 10-2011-0078707

(51) Int. Cl. H01L 41/053

(52) U.S. Cl. 310/327

(57) ABSTRACT

Disclosed herein is an ultrasonic sensor including: a case including an inner space formed therein and including an electrode layer formed on an inner side wall surface thereof; a piezoelectric element seated on the electrode layer on a lower surface of the case, configured in a stack type, and including anode and cathode terminals formed on an outer peripheral surface thereof; a sound absorbing material fixed to an upper portion of the piezoelectric element; and first and second lead wires led from the outside of the case and electrically connected to the electrode layer formed on the inner side wall surface of the case.

### CROSS REFERENCE(S) TO RELATED APPLICATIONS

This application claims the benefit under 35 U.S.C. Section 119 of Korean Patent Application Serial No. 10-2011-0078707, entitled “Ultrasonic Sensor” filed on Aug. 8, 2011, which is hereby incorporated by reference in its entirety into this application.

### BACKGROUND OF THE INVENTION

1. Technical Field

The present invention relates to an ultrasonic sensor, and more particularly, to an ultrasonic sensor in which an electrode layer is formed on an inner wall surface of a case made of a non-conductive material and a piezoelectric element seated on a bottom surface of the case is configured in a stack type to facilitate connection of a lead wire while doubling vibration force of the piezoelectric elements.

2. Description of the Related Art

Generally, two kinds of ultrasonic sensors, that is, a piezoelectricity type ultrasonic sensor and a magnetostriction type ultrasonic sensor have been mainly used as an ultrasonic sensor. The piezoelectricity type ultrasonic sensor uses a phenomenon in which when pressure is applied to an object such as a crystal, a PZT (a piezoelectric material), a piezoelectric polymer, and the like, voltage is generated, and when voltage is applied thereto, vibration is generated. The magnetostriction type ultrasonic sensor uses a Joule effect (a phenomenon in which when a magnetic field is applied, vibration is generated) and a Villari effect (a phenomenon in which when stress is applied, a magnetic field is generated) generated in an alloy of iron, nickel, and cobalt, etc.

An ultrasonic element may be an ultrasonic generator simultaneously with being an ultrasonic sensor. The reason is that the piezoelectricity type ultrasonic sensor senses an ultrasonic wave by voltage generated by applying ultrasonic vibration to a piezoelectric element and generates an ultrasonic wave by vibration generated by applying voltage to the piezoelectric element. In addition, the reason is that the magnetostriction type ultrasonic sensor generates an ultrasonic wave by the Joule effect and senses an ultrasonic wave by the Villari effect.

Currently, a piezoelectricity type ultrasonic sensor using a piezoelectric element has generally been used. The piezoelectricity type ultrasonic sensor has a structure in which the piezoelectric element is seated in an inner portion of a case and an ultrasonic wave generated in the piezoelectric element is discharged to the outside through the case. In the ultrasonic sensor having this structure, since the case serves as an electrode of the piezoelectric element, it is made of a conductive material and is adhered to the piezoelectric element by a conductive adhesive in a state in which it is electrically connected thereto.

Further, in a general ultrasonic sensor, a piezoelectric element is disposed on a bottom surface of a case, and a nonwoven fabric and a substrate are sequentially stacked on an upper portion thereof and then fixed to an inner portion of the case using a molding material, in order to easily discharge ultrasonic vibration of the piezoelectric element to the outside. Generally, a single layer type piezoelectric is mounted, such that ultrasonic vibration performance is slightly deteriorated.

In addition, a connection line for electrical connection between the piezoelectric element, which is an internal component, and a lead wire need be separately provided at the time of assembling of the ultrasonic sensor and is not easily fixed in the inner portion of the case, such that an assembling time of the ultrasonic sensor increases.

### SUMMARY OF THE INVENTION

An object of the present invention is to provide an ultrasonic sensor in which an electrode layer is formed on an inner wall surface of a case and a piezoelectric element seated on an inner portion of the case is configured in a stack type to facilitate connection of electrodes while doubling vibration force of the piezoelectric elements, such that assembling mass productivity may be improved.

According to an exemplary embodiment of the present invention, there is provided an ultrasonic sensor including: a case including an inner space formed therein and including an electrode layer formed on an inner side wall surface thereof; a piezoelectric element seated on a lower surface of the case, configured in a stack type, and including anode and cathode terminals formed on an outer peripheral surface thereof; a sound absorbing material fixed to an upper portion of the piezoelectric element; and first and second lead wires led from the outside of the case and electrically connected to the electrode layer formed on the inner side wall surface of the case.

The ultrasonic sensor may further include a molding material injected and cured into an inner portion of the case to thereby fix the sound absorbing material and the substrate.

The case may be made of a conductive material or a non-conductive material, and when the case is made of the conductive material, an insulating layer may be first formed on the inner side wall surface of the case and the electrode layer may be then formed on the insulating layer.

The insulating layer may be formed by anodizing, and the case may be made of an aluminum (Al) material when the insulating layer is formed by the anodizing.

When the case is made of the non-conductive material, the electrode layer may be formed directly on the inner side wall surface of the case by a method such as a plating method, a coating method, or the like.

The piezoelectric element may be configured in the stack type and be stacked as even number layers so that the anode and cathode terminals are formed at both sides thereof.

The electrode layer formed in the case may be short circuited on the bottom surface of the case to thereby be divided into anode and cathode electrode layers to which each of the anode and cathode terminals of the piezoelectric element is connected.

### BRIEF DESCRIPTION OF THE DRAWINGS

FIG. 1 is a perspective view of an ultrasonic sensor according to an exemplary embodiment of the present invention;

FIG. 2 is a cross-sectional view of the ultrasonic sensor according to the exemplary embodiment of the present invention;

FIG. 3 is a partially enlarged cross-sectional view of the ultrasonic sensor shown in FIG. 2; and

FIG. 4 is an enlarged cross-sectional view of an ultrasonic sensor according to another exemplary embodiment of the present invention.

### DESCRIPTION OF THE PREFERRED EMBODIMENTS

The acting effects and technical configuration with respect to the objects of an ultrasonic sensor according to the present invention will be clearly understood by the following description in which exemplary embodiments of the present invention are described with reference to the accompanying drawings

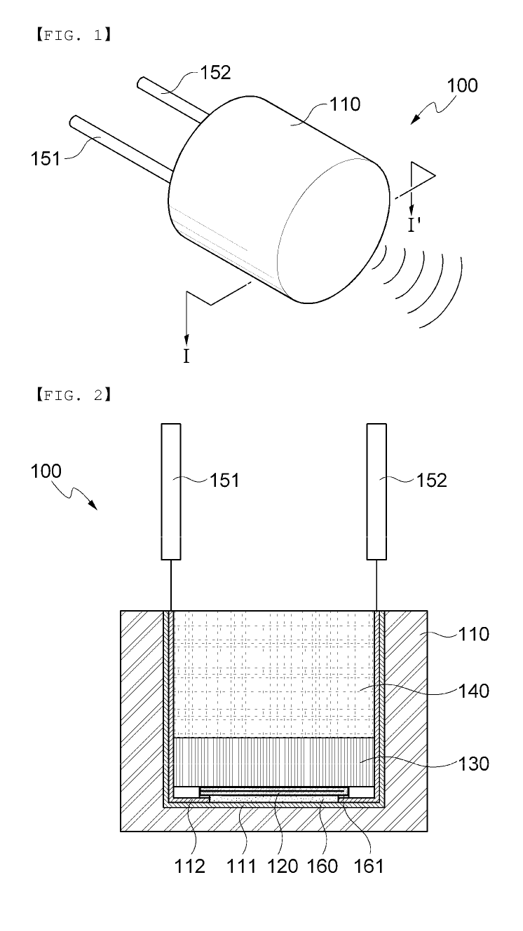

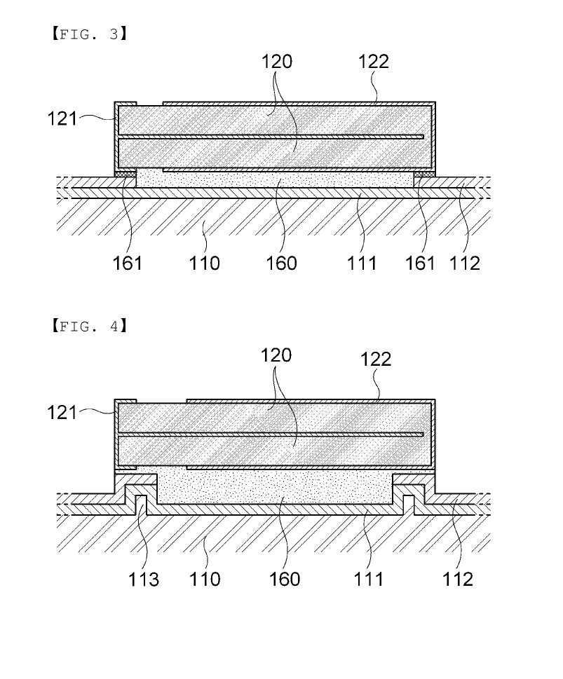

First, FIG. 1 is a perspective view of an ultrasonic sensor according to an exemplary embodiment of the present invention; FIG. 2 is a cross-sectional view of the ultrasonic sensor according to the exemplary embodiment of the present invention; and FIG. 3 is a partially enlarged cross-sectional view of the ultrasonic sensor shown in FIG. 2.

As shown, an ultrasonic sensor 100 according to an exemplary embodiment of the present invention may be configured to include a case 110 including an inner space formed therein and including an electrode layer 112 formed on an inner side wall surface thereof, a stack type piezoelectric element 120 seated on a bottom surface of the case 110, a sound absorbing material 130 mounted on an upper portion of the piezoelectric element 120, and a molding material 140 filled in the inner space of the case 110.

Here, the ultrasonic sensor 100 according to the exemplary embodiment of the present invention further includes two lead wires, that is, first and second lead wires 151 and 152, led from the outside of the case 110, wherein the two lead wires 151 and 152 are electrically connected to a power supply or an external device to serve to apply power to the ultrasonic sensor 100, thereby generating vibration in the piezoelectric element 120 and transfer voltage generated by receiving, in the piezoelectric element 120, an ultrasonic wave returned to the piezoelectric element 120 through reflection on an object to be measured in an ultrasonic wave generated in the piezoelectric element 120 to the external device.

The case 110 may have a cylindrical shape or a box shape, include the inner space into which the piezoelectric element 120, the sound absorbing material 130, and portions of the lead wires 151 and 152 are inserted, and include the electrode layer 112 formed on the inner side wall surface thereof.

The electrode layer 112 may be short circuited on the bottom surface of the case 110 to thereby be divided into electrode layers to which each of anode and cathode terminals 121 and 122 is connected and may be formed on the inner side wall surface of the case 110 by performing an application method such as a plating method, a coating method, or the like, thereon.

The piezoelectric element 120 seated on the bottom surface of the case 110 may be configured in a stack type in which a plurality of piezoelectric elements are stacked and may include the anode and cathode terminals 121 and 122 each formed at both sides thereof.

The piezoelectric element 120 may be formed by stacking at least two piezoelectric elements, that is, the plurality of piezoelectric elements as shown in the accompanying drawings, and may have even number layers such as two layers, four layers, six layers, or the like, so that the anode and cathode terminals 121 and 122 are formed at both sides thereof.

Therefore, in the case of the piezoelectric element 120 seated in the inner portion of case 110, ultrasonic vibration discharged to the outside may be improved by 0.5 to 2 times due to overlapped vibration of the plurality of stacked piezoelectric elements, as compared to the piezoelectric element according to the related art formed of a single layer.

In addition, the piezoelectric element 120 receives power through the first and second lead wires 151 and 152 connected to the electrode layers 112 to which each of the anode and cathode terminals 121 and 122 is connected to thereby generate ultrasonic vibration while being repeatedly extended and contracted according to the polarity of current or receives an ultrasonic wave reflected on an external object to be measured to thereby transfer a converted signal to the external device.

As described above, since the piezoelectric element 120 is electrically connected to the first and second lead wires 151 and 152 through the electrode layer 112 in the case 110, the ultrasonic sensor 100 according to the present embodiment need not include a separate substrate connecting the piezoelectric element 120 to the external device through a circuit or transferring a signal by ultrasonic wave reception in the case 110, thereby making it possible to minimize the number of components in the ultrasonic sensor and implement slimness and lightness thereof.

Meanwhile, the case 110 may be made of a conductive material or a non-conductive material. When the case 110 is made of the conductive material, the electrode layer may not be formed directly on the inner side wall surface of the case 110 made of the conductive material. Therefore, after an insulating layer 111 is formed, the electrode layer 112 may be formed on a surface of the insulating layer 111.

The insulating layer 111 may be formed on the inner side wall surface of the case 110 by performing anodizing thereon. At the time of the anodizing, the case 110 may be made of an aluminum (Al) based metal material.

Next, when the case 110 is made of the non-conductive material, the electrode layer 112 may be formed directly on the inner side wall surface of the case 110 by performing an application method such as a plating method, a coating method, or the like, thereon. In this case, a separate protective layer (not shown) may be further formed in order to improve close adhesion performance of the electrode layer 112 between the inner side wall surface of the case 110 and the electrode layer 112.

The case 110 and the piezoelectric element 120 configured as described above may be closely adhered and coupled to each other through an adhesive 160. When the anode and cathode terminals 121 and 122 formed at both sides of the piezoelectric element 120 are bonded to the electrode layers 112 by an adhesive 161, the piezoelectric element 120 may be closely adhered and coupled to the case 110 through a non-conductive adhesive 160 in order to prevent a short-circuit from being generated due to electrical connection between the respective electrodes.

In this configuration, since the anode and cathode terminals 121 and 122 of the piezoelectric element 120 may be insulated from each other through the non-conductive adhesive 160, the anode and cathode terminals 121 and 122 may be closely adhered and coupled to the electrode layers 112 through a conductive adhesive 161 at portions at which they are connected to the electrode layers 112.

In addition, as the non-conductive adhesive 160 or the conductive adhesive 161, an epoxy based adhesive may be used.

Meanwhile, FIG. 4 is an enlarged cross-sectional view of an ultrasonic sensor according to another exemplary embodiment of the present invention.

As shown, an ultrasonic sensor 100 according to the present embodiment includes a short-circuited electrode layer 112 formed on a bottom surface of a case 110 and a stack type piezoelectric element 120 closely adhered and coupled to the bottom surface of the case 110 through a non-conductive adhesive 160, wherein the bottom surface of the case 110 has the electrode layer 112 formed thereon.

Components of the ultrasonic sensor other than a component for coupling the case and the piezoelectric element to each other according to the present embodiment shown in FIG. 4 are the same as those of the ultrasonic sensor according to the exemplary embodiment described above and shown in FIGS. 1 to 3. Therefore, a detailed description thereof will be omitted below. In addition, the same reference numerals will be used to describe the same components as the components of the ultrasonic sensor according to the exemplary embodiment described above.

According to the present embodiment, the case 110 includes protrusion parts 113 formed at portions at which it contacts anode and cathode terminals 121 and 122 of the piezoelectric element 120, and the electrode layer 112 may be extended to an upper portion of the protrusion part 113.

The non-conductive adhesive 160 is injected between an inner side of the protrusion part 113 and the piezoelectric element 120, thereby making it possible to closely adhere and couple the piezoelectric element 120 and the case 110 to each other. Here, since an adhesion layer between the anode and cathode terminals 121 and 122 of the piezoelectric element 120 and the electrode layer 112 that are closely adhered to each other through the non-conductive adhesive 160 are configured to have a thickness thinner than that of an adhesion layer between the piezoelectric element 120 and the case 110 in the inner side of the protrusion parts 113, the electrode layer 112 and each of the anode and cathode terminals 121 and 121 maybe electrically connected to each other.

That is, the non-conductive adhesive 160 has a thickness of about 10 μm in the inner side of the protrusion part 113 of the case 110; however, it has a thickness of 2 to 5 μm at portions at which the anode and cathode terminals 121 and 122 of the piezoelectric element 120 are bonded to the electrode layer 112, such that the electrode layer 112 and each of the anode and cathode terminals 121 and 121 may be electrically connected to each other.

As a result, according to the present embodiment, a conductive adhesive is not used, thereby making it possible to further reduce a manufacturing cost.

In addition, according to the present embodiment, each of bonding surfaces of the electrode layer 112 and the anode and cathode terminals 121 and 122 that are bonded by the non-conductive adhesive 160 is formed as a concave-convex surface having roughness, thereby making it possible to further facilitate electrical connection through the non-conductive adhesive.

The piezoelectric element 120 described in the exemplary embodiments of the present invention may include the sound absorbing material 130 disposed on an upper portion thereof, wherein the sound absorbing material 130 is generally made of a nonwoven fabric, or the like. The sound absorbing material 130 is closely adhered to the upper portion of the piezoelectric elements 120 to thereby serve to reduce reverberation which appears after the ultrasonic wave is generated in the piezoelectric element 120.

The reason why the reverberation of the piezoelectric element 120 is reduced through the sound absorbing material 130 is as follows: Since the piezoelectric element 120 serves to sense an ultrasonic wave returned to the piezoelectric element through reflection on an object to be measured in an ultrasonic radiated to the outside as well as serves to generate an ultrasonic wave, the reverberation which appears after the ultrasonic wave is generated need be completely removed in order to easily sense the reflected ultrasonic wave and reduce a sensing time.

In addition, the sound absorbing material 130 has a side closely adhered to the inner side wall surface of the case 110 on the upper portion the piezoelectric element 120, thereby making it possible to prevent the molding material 160 from being filled in the vicinity of the piezoelectric element 120 when the molding material 160 is injected into the inner portion of the case 110.

As described above, the piezoelectric element 120 generates vibration through extension and contraction in a longitudinal direction when current is applied thereto. When the molding material 140 is filled in the vicinity of the piezoelectric element 120, it is difficult to generate the vibration through the extension and contraction, such that it may be difficult to generate an ultrasonic wave at a frequency capable of being sensed by a sensor. Therefore, it is preferable to prevent to the molding material 140 from being filled in the vicinity of piezoelectric element 120.

The molding material 140 is injected into the inner portion of the case 110. More specifically, the molding material 140 is filled from an upper surface of the sound absorbing material 130 up to an upper end of the case and cured, thereby making it possible to fix the sound absorbing material 130 and the connection lines connected to a pair of lead wires 151 and 152 at predetermined positions and protect the sound absorbing material 130 and the connection lines from external impact or shaking.

Meanwhile, the piezoelectric element 120 seated on the bottom surface of the case 110 has a capacitance value that may be changed according to an external temperature. Due to this change in the capacitance value, reverberation vibration of the piezoelectric element 120 increases at a low temperature (−40° C. or less), such that a malfunction of a system may be generated, and sensitivity of the piezoelectric element 120 is deteriorated at a high temperature (80° C. or more), such that a sensing distance may be reduced.

In order to prevent a defect from being generated in the piezoelectric element 120 according to the change in an external temperature as described above, a temperature compensation capacitor (not shown) may be mounted.

As described above, with the ultrasonic sensor according to the exemplary embodiment of the present invention, the electrode layer is formed on the inner side wall surface of the case, thereby making possible to easily perform electrode connection through the lead wire. In addition, a separate substrate for electrical connection is not required, thereby making it possible to easily assemble the ultrasonic sensor and improve mass productivity of the ultrasonic sensor.

Further, with the ultrasonic sensor according to the exemplary embodiment of the present invention, the piezoelectric element mounted on the bottom surface of the case is configured in the stack type and is electrically connected to the electrode layer formed on the inner side wall surface of the case, thereby making it possible to double vibration force of the piezoelectric element.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. An ultrasonic sensor comprising:
a case including an inner space formed therein and including an electrode layer formed on an inner side wall surface thereof;
a piezoelectric element seated on the electrode layer on a lower surface of the case, configured in a stack type, and including anode and cathode terminals formed on an outer peripheral surface thereof;
a sound absorbing material fixed to an upper portion of the piezoelectric element; and
first and second lead wires led from the outside of the case and electrically connected to the electrode layer formed on the inner side wall surface of the case.

2. The ultrasonic sensor according to claim 1, further comprising a molding material injected and cured into an inner portion of the case to thereby fix the sound absorbing material and the substrate.

3. The ultrasonic sensor according to claim 1, wherein the case is made of a conductive material or a non-conductive material.

4. The ultrasonic sensor according to claim 3, wherein when the case is made of the conductive material, an insulating layer is first formed on the inner side wall surface of the case and the electrode layer is then formed on the insulating layer.

5. The ultrasonic sensor according to claim 3, wherein when the case is made of the non-conductive material, the electrode layer is formed directly on the inner side wall surface of the case.

6. The ultrasonic sensor according to claim 4, wherein the electrode layer is formed by any one application method of a plating method and a coating method.

7. The ultrasonic sensor according to claim 5, wherein the electrode layer is formed by any one application method of a plating method and a coating method.

8. The ultrasonic sensor according to claim 4, wherein the case is made of an aluminum material, and the insulating layer is formed on the inner side wall surface of the case by performing anodizing thereon.

9. The ultrasonic sensor according to claim 4, wherein the electrode layer is short circuited on the bottom surface of the case to thereby be divided into anode and cathode electrode layers to which each of the anode and cathode terminals of the piezoelectric element is connected.

10. The ultrasonic sensor according to claim 5, wherein the electrode layer is short circuited on the bottom surface of the case to thereby be divided into anode and cathode electrode layers to which each of the anode and cathode terminals of the piezoelectric element is connected.

11. The ultrasonic sensor according to claim 1, wherein the piezoelectric element is configured in the stack type and is stacked as even number layers.

12. The ultrasonic sensor according to claim 1, wherein the piezoelectric element is closely adhered and coupled to the case through a non-conductive adhesive.

13. The ultrasonic sensor according to claim 12, wherein the conductive adhesive is applied to portions at which the anode and cathode terminals of the piezoelectric element are connected to the electrode layer.

14. The ultrasonic sensor according to claim 12, wherein the case includes protrusion parts formed at portions at which it contacts the anode and cathode terminals of the piezoelectric element.
